(19) United States
(12) Patent Application Publication
(10) Pub. No.: US 2005/0104078 A1
(43) Pub. Date: May 19, 2005

(54) Light-emitting diode having chemical compound based reflective structure

(75) Inventors: Wei-Tai Cheng, Tainan Hsien (TW); Jui-Hung Yeh, Chung Li City (TW)

Correspondence Address: TROXELL LAW OFFICE PLLC, SUITE 1404, 5205 LEESBURG PIKE, FALLS CHURCH, VA, 22041, US

(73) Assignee: Ite Compound Semiconductor Corporation

(21) Appl. No.: 10/705,929

(22) Filed: Nov. 13, 2003

(51) Int. Cl. H01L 33/00

(52) U.S. Cl. 257/98; 257/99

(57) ABSTRACT

A light-emitting diode (LED) includes a plurality of reflective layers stacked over each other and each comprising a distributed Bragg reflector, a substrate, an N type semiconductor formed on the substrate, a light emitting layer formed on the N type semiconductor layer and a P type semiconductor formed on the light emitting layer. The stack of the reflective layers is formed under the substrate or the stack is formed between the substrate and the N type semiconductor layer. The reflective layers receive and reflect light incident at different angles thereby alleviating escape of light from the light emitting diode and enhancing overall brightness of the light emitting diode.

### FIELD OF THE INVENTION

The present invention generally relates to the filed of light-emitting diodes (LEDs), and in particular to an LED having reflection structure comprising a plurality of reflective layers of chemical compounds stacked over each other whereby light traveling toward the reflection structure at different incident angles are substantially reflected by the reflective layers so as to eliminate undesired escape of light from the LED and to enhance the overall brightness of the LED for better use in all kinds of display boards, lighting of large space, lighting for display of articles, lighting appliances and advertisement lighting boards.

### BACKGROUND OF THE INVENTION

As shown in FIG. 6 of the attached drawings, a conventional light emitting diode (LED) is comprised of a transparent substrate 5, an N type semiconductor layer 6, a light emitting layer 62 and a P type semiconductor layer 7. The N type semiconductor layer 6 is formed on the transparent substrate 5 and the light emitting layer 62 is formed on the N type semiconductor layer 6. The P type semiconductor layer 7 is formed on the light emitting layer 62. The N type and P type semiconductor layers 6, 7 are respectively provided with an N type electrode 61 and a P type electrode 71. This arrangement forms a conventional structure of light emitting diodes.

The conventional light emitting diode described above has drawbacks. When light is emitted from the light emitting layer 62, the light travels in all directions without any constraint. A portion of the light transmits through surfaces of the N type and P type semiconductor layers 6, 7 as effective light of the LED, while another portion of the light runs toward the transparent substrate 5, becoming an ineffective light. Thus, only a portion of the light emitted from the light emitting layer 62 transmits through the surfaces of the semiconductor layers 6, 7 as effective light, while the remaining portion escapes in a random manner thereby lowering the overall brightness of the light emitting diode. Consequently, the actual brightness of the conventional light emitting diode is lowered than what is theoretically possible.

Another conventional light emitting diode, illustrated in FIG. 7 of the attached drawings, provides one solution to the above technical problem. As shown in FIG. 7, the conventional light emitting diode is comprised of a reflective layer 8 (or a metallic layer), a transparent substrate 5, an N type semiconductor layer 6, a light emitting layer 62 and a P type semiconductor layer 7. The N type semiconductor layer 6 is formed on the transparent substrate 5 and the light emitting layer 62 is formed on the N type semiconductor layer 6. The P type semiconductor layer 7 is formed on the light emitting layer 62. The N type and P type semiconductor layers 6, 7 are respectively provided with an N type electrode 61 and a P type electrode 71. The reflective layer 8 is formed on an undersurface of transparent substrate 5. This arrangement forms the conventional structure of light emitting diode. Due to the provision of the reflective layer 8, the portion of the light that travels toward the transparent substrate 5 is at least partially reflected to transmit through the surfaces of the semiconductor layers 6, 7. However, undesired escape of light is still severe in this conventional structure, consequently leading to poor overall brightness of the light emitting diode. Further, adding the reflective layer 8 in the manufacturing process causes difficult in manufacturing and is an extra expense and labor consumption to the industry.

FIG. 8 of the attached drawings illustrates a further example of the conventional light emitting diode, comprising a substrate 90 on which a reflective layer 91 is formed. An N type semiconductor layer 92 is formed on the reflective layer 91, a light emitting layer 93 is formed on the N type semiconductor layer 92 and a P type semiconductor layer 94 is formed on the light emitting layer 9. A window layer 95 is formed on the P type semiconductor layer 94 and a contact layer 96 is formed on the window layer 95. Electrodes 97, 98 are respectively formed on the substrate 90 and the contact layer 96. Since the reflective layer 91 is formed on the substrate 90, the reflection of the light coming toward the substrate 90 can be improved and the overall brightness of the light emitting diode is thus enhanced. However, the reflective layer 91 of the conventional light emitting diode is subject to a constraint in reflection angle, which is around 20 degrees. Thus, not all the light traveling toward the substrate 90 can be reflected by the reflective layer 91.

### SUMMARY OF THE INVENTION

Thus, a primary object of the present invention is to provide a light emitting diode comprising a stack of reflective layers made of chemical compounds and having different reflection angle for effectively reflecting light having different incident angles thereby substantially eliminating undesired escape of light and enhancing overall brightness of the light emitting diode.

To achieve the above object, in accordance with one aspect of the present invention, a light-emitting diode light emitting diode comprises a plurality of reflective layers stacked on each other to form a reflection structure, each reflective layer comprising a distributed Bragg reflector; a substrate formed on a top surface of the stack of reflective layers; an N type semiconductor layer formed on the substrate; a light emitting layer formed on the N type semiconductor layer; and a P type semiconductor layer formed on the light emitting layer. The stack of reflective layers is formed under the substrate to receive and reflect light from the light emitting diode at different incident angles so as to reduce light escape from the light emitting diode and enhance overall brightness of the light emitting diode.

In another aspect of the present invention, a light-emitting diode comprises a substrate; a stack of reflective layers forming a reflection structure on the substrate, each reflective layer comprising a distributed Bragg reflector; an N type semiconductor layer formed on the stack of the reflective layers; a light emitting layer formed on the N type semiconductor layer; and a P type semiconductor layer formed on the light emitting layer. The stack of the reflective layers is formed between the substrate and the N type semiconductor layer to reflect light of different incident angles thereby alleviating escape of light from the light emitting diode and enhancing overall brightness of the light emitting diodes.

As such, the reflection structure that is comprised of a plurality of reflective layers is capable to reflect light of a wide range of incident angles whereby escape of light from the light emitting diode is alleviated and overall brightness of the light emitting diode is enhanced.

### BRIEF DESCRIPTION OF THE DRAWINGS

The present invention will be apparent to those skilled in the art by reading the following description of preferred embodiments thereof, with reference to the attached drawings, in which:

FIG. 1 is a schematic cross-sectional view of a light emitting diode constructed in accordance with a first embodiment of the present invention;

FIG. 2 schematically shows reflection of light in the light emitting diode of the present invention;

FIG. 3 is a schematic cross-sectional view of a light emitting diode constructed in accordance with a second embodiment of the present invention;

FIG. 4 is a plot of transmittance percentage vs. incident angle, showing comparison of the light emitting diode of the present invention, which has two reflective layers, with a conventional light emitting diode having a single reflective layer;

FIG. 5 is a schematic cross-sectional view of a light emitting diode constructed in accordance with a third embodiment of the present invention;

FIG. 6 is a schematic view of a first conventional light emitting diode, showing the light emission of the conventional light emitting diode;

FIG. 7 is a schematic view of a second conventional light emitting diode, showing the light emission of the conventional light emitting diode;

FIG. 8 is a schematic view of a third conventional light emitting diode, showing the light emission of the conventional light emitting diode; and

FIG. 9 is a plot of reflectivity vs. wavelength, illustrating comparison between the present invention and the conventional designs.

### DETAILED DESCRIPTION OF THE PREFERRED EMBODIMENTS

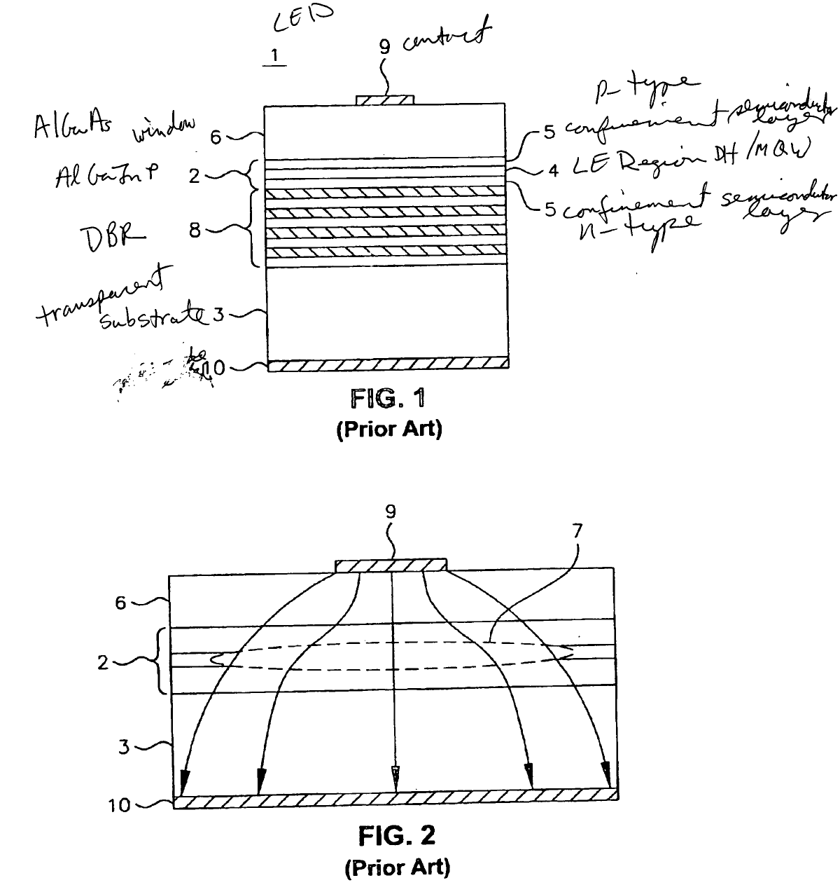

With reference to the drawings and in particular to FIG. 1, a light emitting diode (LED) constructed in accordance with the present invention comprises two reflective layers 1, 1a stacked over each other to form a reflection structure for the LED, a substrate 2, a light emitting layer 32, a N type semiconductor layer 3 and a P type semiconductor layer 4 stacked over each other in sequence. The reflective layers 1, 1a are sequentially deposited on an undersurface of the substrate 2 before the LED die is sliced and the reflective layers 1, 1a function to reflect light coming from the light emitting layer 32 and having different incident angles with respect to the substrate 2. Consequently, undesired escape of light from the LED can be alleviated and the brightness of the LED is enhanced.

In accordance with the present invention, the reflective layers 1, 1a comprise distributed Bragg reflector (DBR) and form a reflection structure together. The reflective layers 1, 1a are each comprised of at least one or more layers of chemical compounds stacked in sequence. Examples of the chemical compounds include oxides, nitrides, carbides and fluorides. The reflective layers 1, 1a have a large range of incident angles, high reflectivity and great bandwidth. The DBR structure of the reflection structure is formed in accordance with the output spectrum of the light emitted from the light emitting layer 32. For example, a 500 nm DBR is employed when the output spectrum is between 500-520 nm, with an additional set or additional sets of DBRs having spectrum greater than 500 nm.

The undersurface of the substrate 2 is mounted to a top face of the reflective layer 1. The substrate 2 is transparent, allowing light to transmit therethrough.

A bottom surface of the N-type semiconductor 3 is mounted to a top surface of the substrate 2. An N type electrode 31 is formed on the N type semiconductor layer 3.

A bottom surface of the light emitting layer 32 is mounted to a top surface of the N type semiconductor layer 3. A bottom surface of the P type semiconductor layer 4 is mounted to a top surface of the light emitting layer 32. A P type electrode 41 is formed on the P type semiconductor layer 4. This forms the light emitting diode in accordance with the present invention.

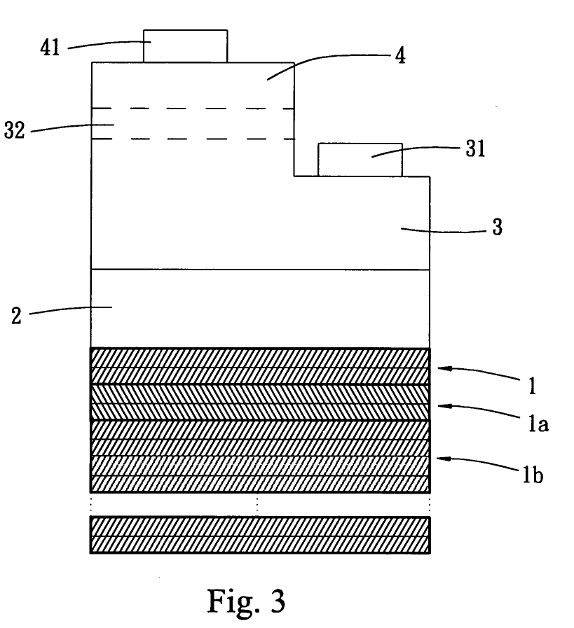

Also referring to FIGS. 2 and 3, when energized, the light emitting layer 32 emits light. A portion of the light transmits through top surface of the P type semiconductor layer 4 while another portion of the light travels through the substrate 2 and reaches the top surface of the reflective layer 1. Due to the DBR structure of the reflective layer 1, the light arriving at the top surface of the reflective layer 1 is reflected by the reflective layer 1. The reflected light travels back through the substrate 2 and then transmits through the N type and P type semiconductor layers 3, 4 whereby the light leaves the LED through the surfaces of the semiconductor layers 3, 4. Thus, the portion of light that travels toward and through the substrate 2 is reflected by the reflective layer 1. A further portion of the light emitted from the light emitting layer 32 may come through the reflective layer 1 and reaches the reflective layer 1a. Such a further portion of light is reflected by the reflective layer 1a and running back through the substrate 2 and the N type and P type semiconductor layers 3, 4.

Apparently, if desired, more than two reflective layers 1, 1a, 1b can be stacked under the underside of the substrate 2 to effectively reflect light coming to the reflective layers 1, 1a, 1b at different incident angles, as illustrated in FIG. 3, whereby undesired escape of light can be substantially eliminated and overall brightness of the LED is enhanced. The reflective layers 1, 1a, 1b can be made of different chemical compounds and have different thickness for optimum reflectivity.

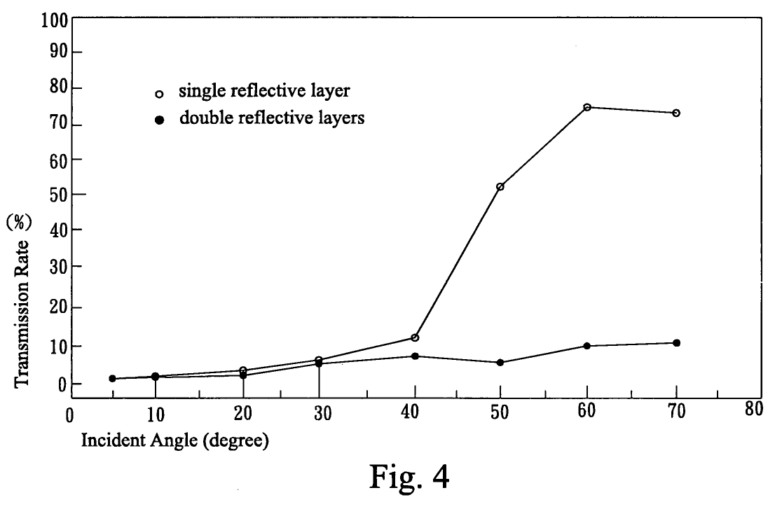

Referring to FIG. 4, the feature of the present invention is a stack of a plurality of reflective layers respectively responsive to different incident angle of light whereby enhanced reflection of the light from the light emitting layer can be realized. For example, for light incident at an incident angle of 60 degrees, the transmission rate of light through a reflection structure comprised of a single reflective layer is approximately 73% while the that for a reflection structure comprised of double reflective layers is lowered down to around 10%. The improvement in reflectivity by using a plurality of stacked reflective layers is quite apparent. Undesired escape of light from the LCD is effectively alleviated and brightness is enhanced. A simple conclusion can be made from the above description that the more layers there are included in a reflection structure of a light emitting diode, the better brightness the LED can provide.

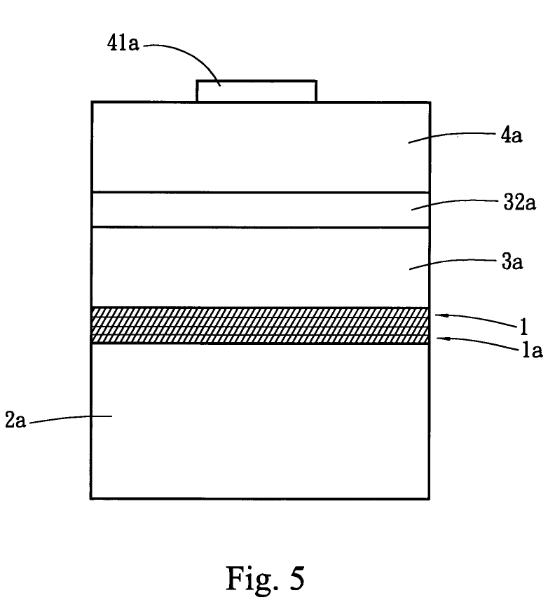

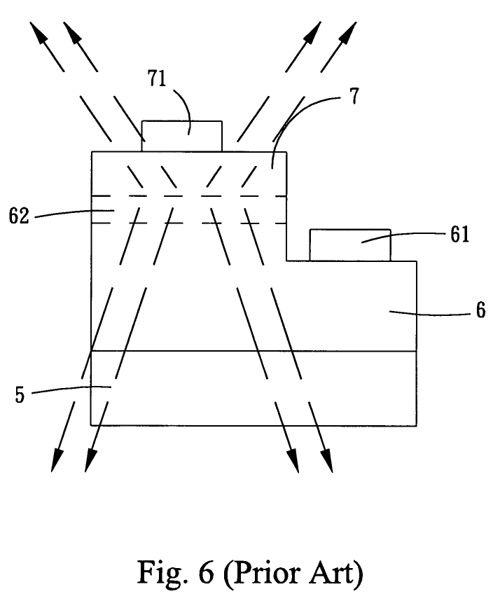

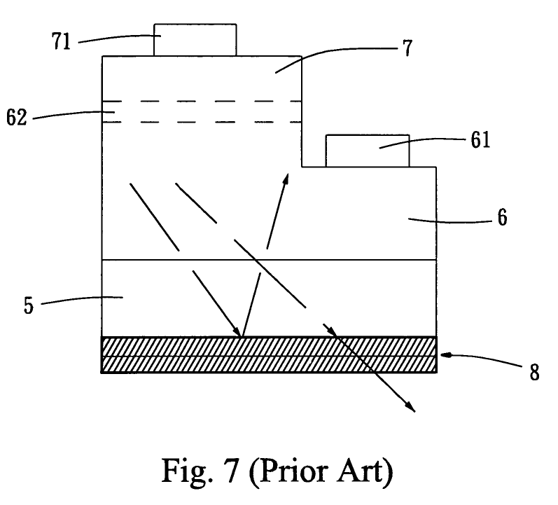

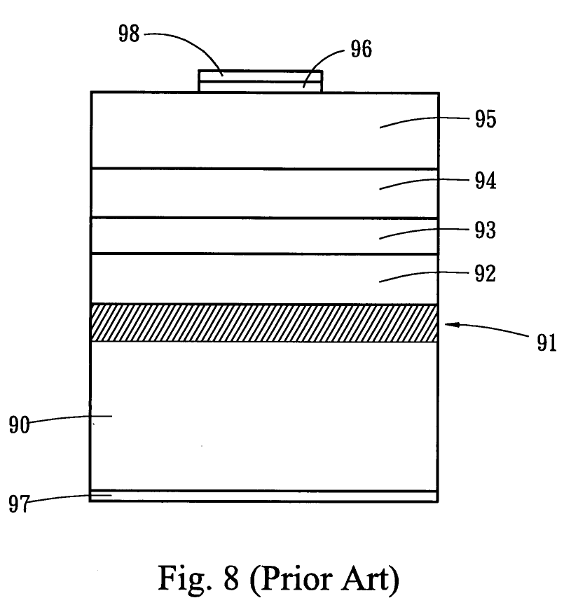

Also referring to FIG. 5, a light emitting diode constructed in accordance with a third embodiment of the present invention is illustrated, the light emitting diode comprises a substrate 2a, two reflective layers 1, 1a stacked in sequence on the substrate 2a, an N type semiconductor layer 3a, a light emitting layer 32a and a P type semiconductor 4a. The P type semiconductor 4a comprises a P type electrode 41a formed thereon. The reflective layers 1, 1a are formed during an epitaxy process of the light emitting diode whereby the reflective layers 1, 1a are formed between substrate 2a and the N type semiconductor 3a to receive and reflect light of different incident angle during the operation of the LED. Thus, escape of light from the LED can be alleviated and overall brightness of the LED is enhanced.

In the third embodiment of the present invention, the reflective layers 1, 1a are distributed Bragg reflectors (DBRs) formed with metal-organic chemical vapor deposition (MOCVD) or molecular beam epitaxy (MBE) to form a reflection structure. Each reflective layer 1, 1a is formed by a stacked pair of sub-layers of chemical compounds selected in accordance with the epitaxy process of the LED. For an example of AlGaInP based light emitting diode, the reflective layers can be made of AlInP, AlGaInP, AlAs and GaAs. For another example of InGaN based light emitting diode, the reflective layers can be made of InGaN, AlGaN and GaN, which are stacked on an upper surface of the substrate 2a. The DBRs are constructed in accordance with the light spectrum of the light emitting layer. For example, if the output light spectrum of the LED is between 590-620 nm, then the reflection structure is comprised of a DBR of 590 nm wavelength and at least one additional DBR of wavelength greater than 590 nm.

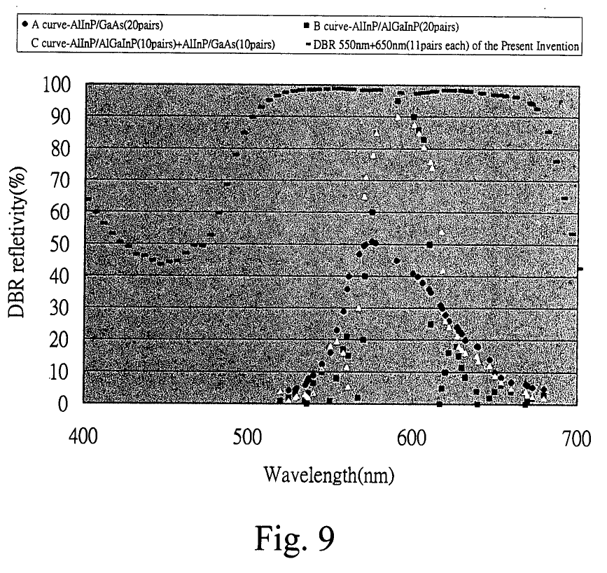

Further referring to FIG. 9, a comparison between the reflectivity of the reflection structure in accordance with the present invention and those of the conventional designs is shown, wherein curves A, B, C shows reflectivity of three conventional LEDs which are obtained from academic paper by F. A. Kish. The remaining curves are reflectivity provided by the reflective layers 1, 1a of the present invention. Clear enough, the reflectivity of the present invention is far better than the conventional designs.

The reflection structure of the LED in accordance with the present invention is comprised of DBR, formed on the undersurface of the substrate before the semiconductor die is sliced. Alternatively, the reflection structure is formed during the epitaxy process of the LED, interposed between the substrate and the N type semiconductor layer. Based on the characteristics of DBR with respect to wavelength of incident light, the stacked DBR structure in accordance with the present invention provides an efficient and effective reflection structure for light emitting diodes. In addition, based on the stacked configuration, the limitation of DBR in angular bandwidth, which imposes limitation in reflection of light of wide spectrum, can be effectively overcome. Difficult caused by the formation of metal layers in the conventional LEDs is thus completely removed, while light incident from different incident angle can be almost completely reflected. Overall brightness of the LED is therefore enhanced.

Although the present invention has been described with reference to the preferred embodiments thereof, it is apparent to those skilled in the art that a variety of modifications and changes may be made without departing from the scope of the present invention which is intended to be defined by the appended claims.

1. A light emitting diode comprising:
a plurality of reflective layers stacked on each other to form a reflection structure, each reflective layer comprising a distributed Bragg reflector;
a substrate formed on a top surface of the stack of reflective layers;
an N type semiconductor layer formed on the substrate;
a light emitting layer formed on the N type semiconductor layer; and
a P type semiconductor layer formed on the light emitting layer;
wherein the stack of reflective layers is formed under the substrate to receive and reflect light from the light emitting diode at different incident angles so as to reduce light escape from the light emitting diode and enhance overall brightness of the light emitting diode.

2. The light emitting diode as claimed in claim 1, wherein the distributed Bragg reflector is formed in accordance with light spectrum of the light emitting diode.

3. The light emitting diode as claimed in claim 1, wherein the substrate is made of transparent material.

4. The light emitting diode as claimed in claim 2, wherein the reflection structure is made of compounds selected from a group consisting of oxides, nitrides, carbides and fluorides.

5. A light emitting diode comprising:
a substrate;
a stack of reflective layers forming a reflection structure on the substrate, each reflective layer comprising a distributed Bragg reflector;
an N type semiconductor layer formed on the stack of the reflective layers;
a light emitting layer formed on the N type semiconductor layer; and
a P type semiconductor layer formed on the light emitting layer;
wherein the reflective layers reflect light of different incident angles to alleviate escape of light from the light emitting diode and enhance overall brightness of the light emitting diodes.

6. The light emitting diode as claimed in claim 5, wherein the distributed Bragg reflector is formed in accordance with light spectrum of the light emitting diode.

7. The light emitting diode as claimed in claim 6, wherein each reflective layer of the stack is formed by at least one stacked pair of compounds that are selected in accordance with material used in epitaxy process of the light emitting diode.

8. The light emitting diode as claimed in claim 7, wherein the material of the light emitting diode comprises AlGaInP, and wherein the compounds for the reflective layers are selected from a group consisting of AlInP, AlGaInP, AlAs and GaAs.

9. The light emitting diode as claimed in claim 7, wherein the material of the light emitting diode comprises InGaN, and wherein the compounds for the reflective layers are selected from a group consisting of InGaN, AlGaN and GaN.

10. The light emitting diode as claimed in claim 5, wherein the reflective layer is formed by metal-organic chemical vapor deposition.

11. The light emitting diode as claimed in claim 5, wherein the reflective layer is formed by molecular beam epitaxy.
